(19) United States
(12) Patent Application Publication
(10) Pub. No.: US 2004/0077140 A1
(43) Pub. Date: Apr. 22, 2004

(54) Apparatus and method for forming uniformly thick anodized films on large substrates

(76) Inventors: Panayotis C. Andricacos, Croton-on-Hudson, NY (US); Roy Arthur Carruthers, Stormville, NY (US); Stephan Alan Cohen, Wappingers Falls, NY (US); John Michael Cotte, New Fairfield, CT (US); Lynne M. Gignac, Beacon, NY (US); Kenneth Jay Stein, Sandy Hook, CT (US); Keith T. Kwietniak, Highland Falls, NY (US); Seshadri Subbanna, Brewster, NY (US); Horatio Seymour Wildman, Wappingers Falls, NY (US); David Earle Seeger, Congers, NY (US); Andrew Herbert Simon, Fishkill, NY (US)

Correspondence Address: CONNOLLY BOVE LODGE & HUTZ LLP, SUITE 800, 1990 M STREET NW, WASHINGTON, DC, 20036-3425, US

(21) Appl. No.: 10/270,486

(22) Filed: Oct. 16, 2002

(51) Int. Cl. C25D 5/00; H01L 21/8238; H01L 21/31; H01L 21/469

(52) U.S. Cl. 438/240; 438/785; 438/782; 205/80

(57) ABSTRACT

A uniformly thick oxide film on a substrate is formed by using an anodization apparatus which deposits a blanket precursor film on a surface of a substrate; provides electrical contact to the precursor film; moves the precursor film into contact with an electrolyte solution such that substantially all electrically conductive surfaces, e.g., pin contacts, the substrate edge and a backside of the substrate are electrically isolated from the electrolyte; ensures that the surface of the precursor film on the substrate is in direct contact with the electrolyte solution; and which applies an anodizing current and/or voltage between the precursor film and a counter electrode so as to compensate for a voltage drop resulting from the presence of the electrolyte.

### BACKGROUND OF THE INVENTION

This invention relates to a method and apparatus for forming uniformly thick anodized films on substrates.

The continued progress in improving integrated circuit (IC) performance, either by device scaling or by the incorporation of passive devices into chips or packages, requires the development of new materials to allow faster and smaller devices to be manufactured. Materials with higher dielectric constants (“high k”), for example Ta₂0₅ (k≈25 or higher), Al₂0₃, Hf0₂ and Zr0₂, must replace traditional materials such as Si0₂ used in the microelectronics industry. These materials as well as the processes for depositing them must be compatible with materials and processes currently used in IC manufacturing. Methods for depositing these materials range from sputtering to atomic layer chemical vapor deposition. A less popular but equally powerful method entails the deposition of the parent metal/alloy followed by electrochemical anodization to form the high dielectric constant oxide. Anodization offers a low cost, low temperature, easily integrated process for forming high dielectric constant materials.

Anodization has been reported in the literature back as early as the 1950's for a wide range of applications including protective coatings, porous surface layers, insulating layers and capacitor dielectric layers. More recent potential applications in the semiconductor industry include gate dielectrics for FET devices, as described by U.S. Pat. No. 6,096,590 to Saenger et al. and capacitor dielectrics for on-chip MIM capacitors as demonstrated by Duenas et al. (S. Duenas, E. Castan, J. Barbolla, R. R. Kola, and P. A. Sullivan, “Use of Anodic Tantalum Pentoxide for High-Density Capacitor Fabrication,”J. Mat. Sci: Mat. Electronics, 10, 379-384 (1999)). Applications of this nature require uniform film thickness across relatively large area substrates. The process of anodization can be described as the electrochemical oxidation of a metal such as Al, Ta, Hf, Zr, W, Y, Nb, Ti, Bi, and Sb, for example, to form the corresponding oxide, by a mechanism of solid state diffusion under high field strength.

The electrochemical system used for anodization typically consists of a workpiece to be coated as the anode, an inert metal cathode such as Pt or platinized Ti, a conducting electrolyte, for example, sulfuric acid or citric acid, and an external power supply. The anode may be connected to the positive output and the cathode may be connected to the negative output of the power supply and submerged in the electrolyte. Anodization may be accomplished by applying a constant current, a constant voltage, or a combination of a constant current and a constant voltage.

Anodization involves the use of an electrolytic medium whose conductivity can be either relatively high (e.g., 21 S/m), or relatively low (e.g., 0.01 S/m) depending on the chemical identity of the precursor film, and the final properties required of the oxide. Thus, aluminum anodization can take place in relatively concentrated sulfuric acid (approximately 5% or greater) whose conductivity is relatively high, e.g., 21 S/m, while tantalum anodization can take place in dilute citric acid (as low as 0.01%) whose conductivity is relatively low, e.g., 0.01 S/m.

As discussed above, anodization may be accomplished by a combination of constant currents and/or voltages. A popular anodization protocol is one in which a constant current is applied until the voltage difference between the electrodes (e.g., cathode and anode) used in the process attains a certain preselected value, at which point one switches to constant voltage control.

The value of the voltage (V_{anode}) may be determined by the equation

V_{anode}=E×d, [1]

where E is the internal oxide field (in V/Å), and d is the desired oxide thickness in Angstroms (Å). A frequent error in conventional approaches is to confuse the value of V_{anode} with the output of the power supply, V_{supply}. These two voltages can be very different, depending on the electrolyte resistance according to the equation:

V_{supply}=V_{anode}+IR_{electrolyte}+V_{cathode}, [2]

where IR_{electrolyte} is the ohmic voltage drop across the electrolyte which depends on the value of the current (I) that flows through the cell, and which may not be constant in time. V_{cathode} is the voltage drop across the counter electrode (or cathode), also a function of time, but usually significantly less that either of the other two voltages.

For instance, if the counter electrode is a platinum (Pt) surface and the reaction that occurs on it during anodization is H₂ evolution, the voltage needed to carry on the H₂ evolution is a small fraction of a volt, relative to the tens of volts required by the other two terms.

Equation [2] thus assumes an approximate form

V_{supply}=V_{anode}+IR_{electrolyte}. [3]

The IR_{electrolyte} term, if large, can lead to completely erroneous results, and it is not known in the literature to conventionally correct for this term. For instance, if one were to scale up an anodization process from a 200 mm wafer to a relatively larger 300 mm wafer, while using the same value of V_{supply}, films of significantly lower thickness would result, especially if the precursor film comprised Ta, and if the electrolyte was citric acid, for example.

Another circumstance which necessitates electrolyte resistance compensation is anodization-through-a-mask, a process wherein the substrate is covered with a mask, and anodization occurs only where the underlying precursor film is exposed to the electrolyte. If coverage by the masking material varies from mask set to mask set, the anodization current also varies, since it is the current density that is maintained constant in this process. A mask set with higher coverage of the precursor film with masking material requires less current. In this case, the thickness of the resulting film would be higher than in a mask set with less coverage, since the IR_{electrolyte} voltage drop is lower and, consequently, more of the applied voltage is dedicated to the anodization process. In the absence of voltage compensation due to ohmic loss, an unacceptable dependence of the thickness of anodized film on mask pattern density may result.

In the protocol described above for Ta in citric acid, for example, an applied voltage of 25 volts would be recommended in the literature to obtain a 500 Angstrom film of Ta₂O₅. However, one finds that values of IR_{electrolyte} in a 200 mm experiment exceed as much as 50 volts, even at relatively low current densities such as 1 mA/cm2 or lower. Therefore, anodizing a 200 mm wafer at 25 volts will lead to no Ta₂O₅ being formed whatsoever. To correct this situation, one needs to compensate for the voltage loss, IR_{electrolyte}. Analogous corrections need also be made in anodization protocols where current is varied linearly with time, as proposed by Konuma et al. in U.S. Pat. No. 5,595,638.

The U.S. Pat. No. 5,595,638 to Konuma et al. describes an anodization process with a linearly increasing current, however Konuma et al. make no mention of a particular apparatus used to achieve oxide uniformity. In fact throughout the literature on anodization, there is no reference or description of a method or apparatus to form an oxide of uniform thickness over large substrates. In this context, the term “large substrate” is meant to describe a substrate having an area greater than approximately 4,000 mm² or so, e.g., a wafer with 3″ diameter.

Aigo et al., in U.S. Pat. Nos. 4,339,319, 4,170,959 and 4,137,867, describe an apparatus based on a so-called “cup cell configuration” with a fountain flow designed for use in electrodeposition processes. Commercial vendors who market electrodeposition tools include Novellus, Semitool, Applied Materials and EEJA. Ebara is another commercial supplier who markets a multi-chamber tool designed exclusively for electrodeposition. Andricacos et al. in U.S. Pat. No. 5,516,412 have described another tool designed for electrodeposition, based on a so-called “paddle cell configuration.”

However, none of the conventional approaches mentioned above provides an anodization tool, apparatus, or method which is capable of forming, by anodization, high dielectric constant oxides having uniform thickness over large substrates, e.g., 200-300 mm semiconductor wafers.

What is needed, then, is an anodization method and apparatus to form high dielectric constant oxides of excellent uniformity over relatively large substrates. What is further needed is an apparatus and method for partially or completely anodizing a precursor film to create a high dielectric constant film over a residual conductor or semiconductor with excellent uniformity of thickness over a relatively large substrate. What is even further needed is an anodization protocol relating to provision of uniformly thick anodized films, especially anodization involving use of constant current steps, and which adjusts to include a correction for the voltage drop IR_{electrolyte}, and which reduces or eliminates an unacceptable dependence of the thickness of the anodized film on a mask pattern density.

### SUMMARY OF THE INVENTION

The claimed invention solves at least one of the aforementioned problems relating to providing an anodized oxide film having a relatively high dielectric constant, which is formed on a relatively large substrate.

In one aspect of the claimed invention, an apparatus which may be used to conduct an anodizing process preferably comprises a cup cell and fountain flow configuration which has a substrate mounted in a wafer carrier assembly, with a precursor film exposed and contacted at the perimeter by electrical contacts. The electrical contacts as well as other edges and sides of the wafer are preferably isolated to prevent exposure to an electrolyte and detrimental coating with an oxide film, dissolution, or evolution of a gas such as 0₂ in preference to the anodization process.

The electrical contacts may be connected to outputs of a controllable power supply, which is preferably controlled to provide a time-phased combination of constant current output, and a constant voltage output. The cup assembly contains a counter-electrode or cathode which is also connected to an output of the controllable power supply. A diffuser plate may also be located in the cup assembly below the wafer carrier and above the cathode.

Electrolyte solution such as citric acid, acetic acid, boric acid phosphoric acid tartaric acid, or sulfuric acid, for example, may be pumped from a separate reservoir into cup assembly through an inlet, to flow over an edge of the cup assembly to form a fountainhead.

The wafer carrier is lowered toward the cup assembly to bring the precursor film into contact with the electrolyte. Power from the controllable power supply is then applied between the precursor film on wafer through isolated electrical contacts and cathode, and anodization of the precursor film commences. The controllable power supply then compensates for the voltage drop due to current flow through the electrolyte.

A second aspect of the present invention which relates to providing a method for forming a uniformly thick oxide film on a large substrate may be realized by using the above apparatus and the following steps:

i) depositing a blanket precursor film which may be the parent metal of the desired oxide to be formed, for example Ta, Al, W, Zr, Hf, Ti, Sb, Y, Bi, or Nb, or an alloy, multilayer, or doped version of such metals;

ii) providing electrical contact to a surface of the precursor film at a substrate edge with either a point or a continuous contact;

iii) bringing the substrate into contact with an electrolyte solution, for example citric acid, acetic acid, boric acid phosphoric acid tartaric acid or sulfuric acid, such that substantially all electrically conductive surfaces, e.g., pin contacts, the substrate edge and a backside of the substrate, are electrically isolated from the electrolyte, while ensuring that the surface of the precursor film is in contact with the electrolyte solution;

iv) applying a time-phased combination of constant current and constant voltage between the precursor film and an inert counter electrode, e.g., Pt or platinized Ti, which is also submerged in the electrolyte.

A third aspect of the present invention is directed to an apparatus used to conduct an anodizing process and which preferably comprises a paddle cell flow configuration which has a substrate mounted in a wafer carrier assembly with a precursor film exposed and contacted at the perimeter by electrical contacts. The electrical contacts as well as other edges and sides of the wafer are electrically isolated from each other.

The paddle cell preferably contains a counter-electrode or cathode placed parallel to the anode. The anode and cathode can be placed in either a vertical or horizontal orientation. A paddle moving parallel to the wafer surface, and executing a reciprocating motion with the aid of an external motor may be used to provide agitation of the electrolyte. An electrolyte solution such as citric acid, acetic acid, boric acid phosphoric acid tartaric acid or sulfuric acid preferably flows between the anode and cathode. The wafer carrier assembly is lowered into the paddle cell flow assembly to bring the precursor film into contact with the electrolyte. Power from a controllable power supply which compensates for an ohmic voltage loss in the electrolyte is then applied between the precursor film on wafer through isolated electrical contacts and cathode, and anodization of the precursor film commences.

A fourth aspect of the present invention relates to a method for using the paddle cell flow apparatus to form a uniformly thick anodized film on a relatively large substrate. The method includes using the above apparatus and includes the following steps:

i) depositing a blanket precursor film which may be the parent metal of the desired oxide to be formed, for example Ta, Al, W, Zr, Hf, Ti, Sb, Y, Bi, or Nb, or an alloy, multilayer, or doped version of such metals;

ii) providing electrical contact to a surface of the precursor film at a substrate edge with either a point or a continuous contact;

iii) placing the substrate into an electrolyte solution, for example citric acid, acetic acid, boric acid phosphoric acid tartaric acid or sulfuric acid, such that substantially all electrically conductive surfaces, e.g., pin contacts, the substrate edge and a backside of the substrate, are electrically isolated from the electrolyte, while ensuring that the surface of the precursor film is in contact with the electrolyte solution;

iv) applying a time-phased combination of constant current and constant voltage between the precursor film and an inert counter electrode, e.g., Pt or platinized Ti, which is also submerged in the electrolyte, to compensate for an ohmic voltage loss in the electrolyte.

Further scope and applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

In the detailed description of the preferred embodiments presented below, reference is made to the accompanying drawings in which:

FIG. 1 provides a schematic representation of the process by which formation of an anodized film of the present invention evolves over time;

FIG. 2 is a schematic representation of one embodiment of anodization apparatus;

FIGS. 3A and 3B provide a indication of the current and voltage characteristics of the method and apparatus of the present invention during an anodization process, showing a difference in voltage with the conventional approach;

FIG. 4 provides transmission electron microscope cross-sectional views of a representative wafer coated with an anodized film formed by the method of the present invention;

FIG. 5 depicts a paddle cell flow type apparatus of an alternative embodiment;

FIG. 6 provides an exemplary arrangement of an electrolyte storage compartment and other components which may be used in combination with the anodization apparatus of either FIGS. 2 or 5;

FIG. 7 shows a representative capacitor structure having a dielectric film formed using the anodization method of the present application; and

FIG. 8 shows a representative transistor structure having a dielectric film formed using the anodization method of the present application.

### DESCRIPTION OF PREFERRED EMBODIMENTS

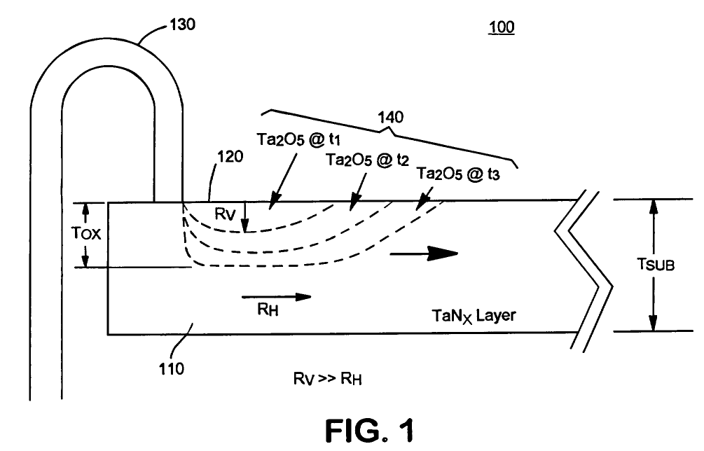

We have found that the formation of uniformly thick anodized films on large substrates occurs by a self-limiting process. Referring now to FIG. 1, a simplified representation of anodizing apparatus 100 is shown. The schematic shows an edge of substrate 110 with precursor top layer 120 and electrical pin contact 130. Upon application of an electric current to precursor top layer 120 through pin contact 130 and a counter-electrode such as Pt (not shown), and in the presence of an appropriate electrolyte, for example, citric acid, formation of oxide film 140 begins in the vicinity of electrical contact 130.

The formation of oxide film 140 (e.g., Ta₂O₅,in this example) in vertical direction R_{V} causes the resistance of the current path between pin contact 130 and the counter-electrode to increase. Propagation of oxide film 140 occurs in horizontal direction R_{H}, resulting in a uniformly thick oxide film with thickness T_{OX}, less than the substrate thickness T_{SUB}, determined by the voltage applied between pin contact 130 and the counter-electrode.

A practical apparatus used to form uniformly thick anodic oxide films on large substrates somewhat resembles tools conventionally used for electroplating processes with fountain flow, paddle cell or other fluid flow configurations. As mentioned above, tools such as these are commercially available from vendors such as Novellus Systems, Semitool, Applied Materials, EEJA, and Ebara.

However, in order to adapt these tools or apparatus for anodizing instead of electroplating, changes to the arrangement and operation of the apparatus are necessary, including:

i) reversing the power supply polarity;

ii) adapting the power supply to execute conversions from constant current to constant voltage operation and vice versa; and

iii) completely isolating electrical contacts from the anodizing solution (which is also done for plating, but for a different purpose).

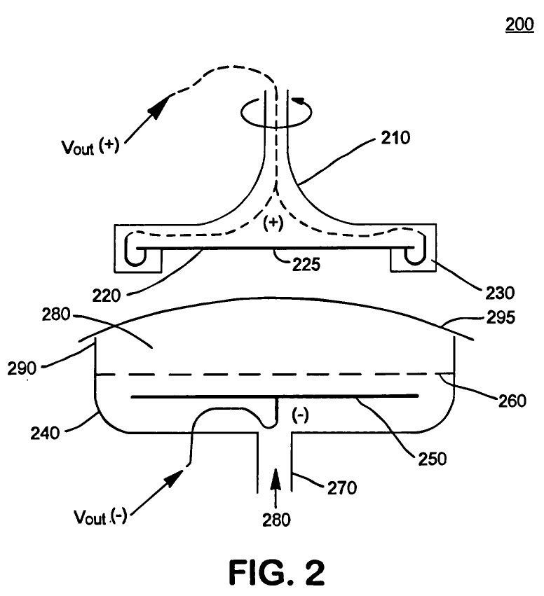

FIG. 2 shows a schematic of anodizing apparatus 200 having a so-called “cup cell and fountain flow” configuration. The substrate or wafer 220 is mounted in wafer carrier assembly 210 with precursor film 225, which is on wafer 220, being exposed and contacted at the perimeter, either with equally spaced isolated electrical contacts 230 of, for example, a pin contact type or a continuous ring contact type about a periphery of wafer 220. Electrical contacts 230 are provided on precursor film 225 close to an edge of the wafer. The term “close”, in this context, refers to, for example, electrical contacts 230 being within between 0.05 to 1 cm, and more preferably 0.05 to 0.5 cm, and most preferably 0.05 to 0.1 cm. distance from the substrate edge. Such a position of the electrical contacts relative to the substrate edge allows more of the surface of the substrate to be anodized, thus reducing waste, as well as maximizing the useable wafer area. Electrical contacts 230 may also contact precursor film 225 at multiple points, arranged symmetrically with respect to the center of the substrate or wafer 220.

Precursor film 225, located on a surface of wafer 220 may be, for example Ta, Al, W, Zr, Hf, Ti, Sb, Y, Bi, or Nb, or an alloy, multilayer, or doped version of such metals. Substrate wafer 220 may also include one or more conducting underlayers, comprising, for example, Al, Ti, TiN, W, Pt, Cr, Mo, or Cu. Wafer 220 may comprise one or more semiconductor layers, such as doped silicon (Si) or poly silicon (Si⁺). The thickness T_{SUB} of wafer 220 should exceed the desired thickness T_{OX} of oxide film 140, as shown in FIG. 1.

Electrical contacts 230 as well as the edges and a backside of wafer 220 are preferably completely isolated to prevent exposure to electrolyte 280. Such relatively complete isolation may be accomplished, for example, by sealing electrical contacts 230 in wafer carrier 210 so that electrolyte 280 is unable to contact electrical contacts, as shown in FIG. 2.

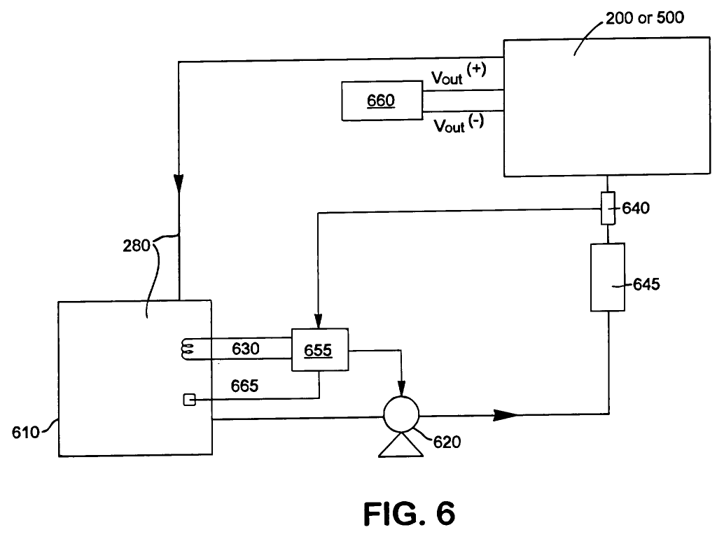

Electrical contacts 230 are connected to a positive output (Vₒᵤₜ⁺) of a controllable power supply 660 (see FIG. 6). Wafer carrier 210 may be arranged to include a motorized gear mechanism (not shown), which causes rotation about a central axis during anodization for more uniform coating of the anodized film on wafer 220, as depicted by the rotation arrow at the top of FIG. 2. Further, the same mechanism may be used to move wafer carrier 210 toward and away from cup assembly 240 to place precursor film 225 into contact with electrolyte solution 280, as well as rotating wafer carrier 210.

Cup assembly 240, which is a container having preferably an inert counter-electrode or cathode 250 therein, which may comprise Pt, for example, and which may be connected to a negative output (Vₒᵤₜ⁻) of controllable power supply 660. The shape of the counter electrode 250 is preferably similar in shape to wafer 220 to encourage uniform formation of the anodized film on precursor film 225.

Optionally, diffuser plate 260 may be located in cup assembly 240 below wafer carrier 210 and above cathode 250 in order to ensure uniform electrolyte flow.

Rotating wafer carrier 210 is lowered toward cup assembly 240 to bring wafer 220, which has precursor film 225 on a surface thereof, into contact with electrolyte 280. Power from the controllable power supply is then applied between the precursor film on wafer 220 through isolated electrical contacts 230 and cathode 250, and anodization of precursor film 225 commences.

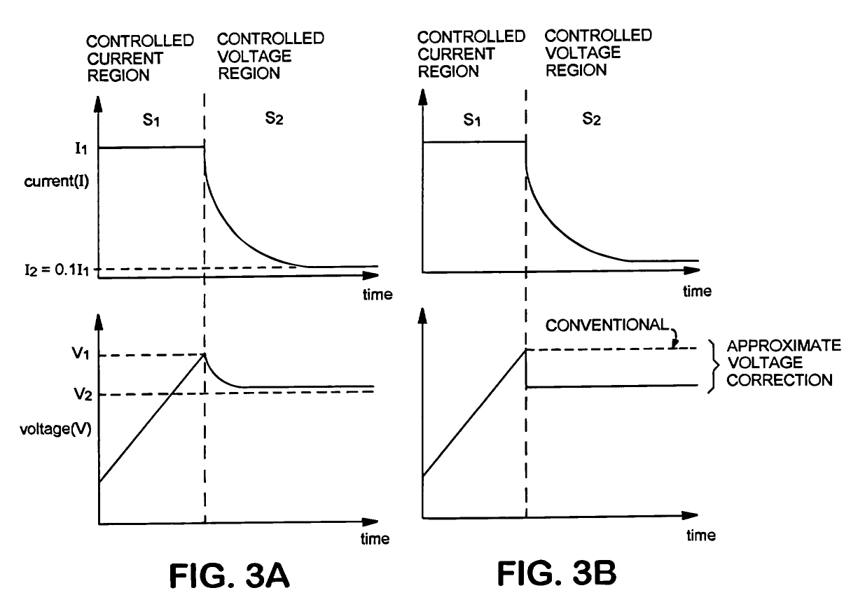

Controllable power supply 660, which is at least capable of producing current-voltage characteristics as illustrated in FIGS. 3A and 3B, may be of a known type of programmable power supply that utilizes a microprocessor, for example, to provide, as needed by the particular process step at specific times, a controlled constant-current output, or a constant-voltage output as required, or as determined by an operator of the anodizing tool or apparatus. An example of a commercially available programmable power supply includes Dynanet Programmable Pulse Power Supply, which may be utilized in a preferred embodiment.

In one aspect of the invention, electrolyte solution 280, such as citric acid, acetic acid, boric acid phosphoric acid tartaric acid, or sulfuric acid, may be pumped from a separate reservoir 610, as shown in FIG. 6, by pump 620 into anodization cell 200, i.e., into cup assembly 240 through inlet 270. Alternatively, in another aspect, electrolyte solution 280 may flow from reservoir 610 by gravity feed, with the flow rate preferably controlled by a throttle valve (not shown). In either case, electrolyte solution 280 enters cup assembly 240 and flows over edge 290 to form fountainhead 295.

Electrolyte flow rate and temperature are preferably kept constant during anodization. For example, an electrolyte flow rate in the range of 0-6 gal/min, and an electrolyte temperature in the range of 10-50° C. generally provide satisfactory results, depending upon the specific electrolyte solution 280 being used, and the concentration of the electrolyte. Such control of electrolyte flow rate and temperature may be accomplished by the arrangement depicted in FIG. 6 which has controller 655 which regulates temperature control 630 to control the electrolyte temperature, and the electrolyte flow rate based upon feedback from temperature sensor 665, and flow rate sensor 640 arranged as shown with respect to anodization apparatus 200. Pump 620, in this instance, may be a variable flow rate pump in order to provide an optimum amount of electrolyte solution 280, based upon feedback from flow rate sensor 640 located in line with the flow of electrolyte 280.

A method for forming a uniformly thick oxide film on a large substrate by anodization may be realized by using the following steps in conjunction with the above-discussed apparatus:

i) depositing a blanket precursor film which may be the parent metal of the desired oxide to be formed, for example Ta, Al, W, Zr, Hf, Ti, Sb, Y, Bi or Nb, or an alloy, multilayer, or doped version of such metals;

ii) providing electrical contact to a surface of the precursor film at the substrate edge with either a point or a continuous contact;

iii) bringing the substrate into contact with an electrolyte solution, for example citric acid, acetic acid, boric acid phosphoric acid tartaric acid or sulfuric acid, ensuring that the surface of the precursor film is in contact with the electrolyte solution;

iv) electrically isolating all electrically conductive surfaces, e.g., pin contacts, substrate edge, and the backside of the substrate, from the electrolyte; and

v) applying a combination of time-phased constant current and constant voltage, between the precursor film and an inert counter electrode or cathode, such as Pt, which is also submerged in the electrolyte.

In a further preferred embodiment of the present invention, the method of forming a uniformly thick anodized film over a large substrate may use a two-step anodizing process to compensate for the undesirable effects of voltage loss due to IR_{electrolyte}, by controlling the anodizing current in a prescribed manner.

An anodization protocol depicted in FIGS. 3A and 3B essentially comprises two steps. In step 1 (S1), in the controlled current region indicated, a constant current is applied, while the voltage increases up to a certain value, e.g., V₁. In step 2 (S2), in the controlled voltage region also indicated in FIG. 3A, a constant voltage is applied for a period of time, preferably determined either by the current attaining a small fraction of its initial value (e.g., 0.1 I₁ or less). The magnitude of the voltage applied in step 2 is essentially equal to the voltage attained at the end of step 1, i.e., V₁. Shown in the upper portion of FIG. 3A is the variation of the current with time during the two-step protocol. As mentioned above, the anodization treatment may apply a constant voltage between the substrate and the counter electrode for a period of time required for the anodization current to drop to a level below 10% of the initial anodization current, or even to a level below 1% of the initial value, to ensure good oxide quality.

According to equation [3], the anodization voltage in the controlled voltage region varies with time, since current I and therefore IR_{electrolyte}, vary with time. To conduct the process under constant voltage conditions, the output voltage V_{supply} of the power supply must be controllably varied, as shown in the bottom plot of FIG. 3A. In other words, the control voltage should decay from V₁ to V₂, where V₂ is (V₁−I₁R_{electrolyte}), and where I₁ is the value of the current at the end of the controlled current region, and which ultimately will decay to zero amps. Since the anodization current decay is relatively fast at the onset of the controlled voltage region as shown in the top plot of FIG. 3A, and programming a power supply to exhibit the exact features of the decay may be impractical, an approximation shown on the bottom plot of FIG. 3B is instead used for ease of implementation. In other words, the control voltage V_{supply} is set at a constant value of V₂=(V₁−I₁R_{electrolyte}) throughout the controlled voltage region. As an approximation, the bottom plot of FIG. 3B shows a step voltage function which may be desirable in some applications.

The exact voltage range of the supply voltage depends on the ultimately desired oxide thickness, and the time for which this voltage is supplied depends on the time required for the current to decay to a preselected value.

For example, for Ta and TaN anodized in dilute electrolytes, oxide film forms at 15-20 Angstrons (Å)/Volt.

The above-described protocol is thus different from the conventional approach previously described, and the difference relates, at least in part, to the approximated voltage correction shown in the bottom plot of FIG. 3B. Application of the approximated voltage correction has application to both one-step and two step anodization processes.

The applied voltage provided by controllable power supply 660 may thus be viewed as consisting of two parts—one which is needed to achieve the desired thickness of the anodized film, and a second portion which compensates for the ohmic voltage drop of the electrolyte.

For example, a blanket TaN precursor film deposited on an Al/Ti/TiN metal stack formed by PVD (sputtering) on a 200 mm silicon wafer was anodized using the process steps and apparatus described above. The anodization conditions consisted of a two-step process. First, constant current anodization at a current density of 0.1 mA/cm² was provided to a maximum voltage of 25 volts. Constant voltage anodization for 30 minutes followed, at which point the anodization current had dropped to less than 3% of the initial value. The average anodic oxide thickness across the wafer was measured by transmission electron microscope (TEM) cross-sections.

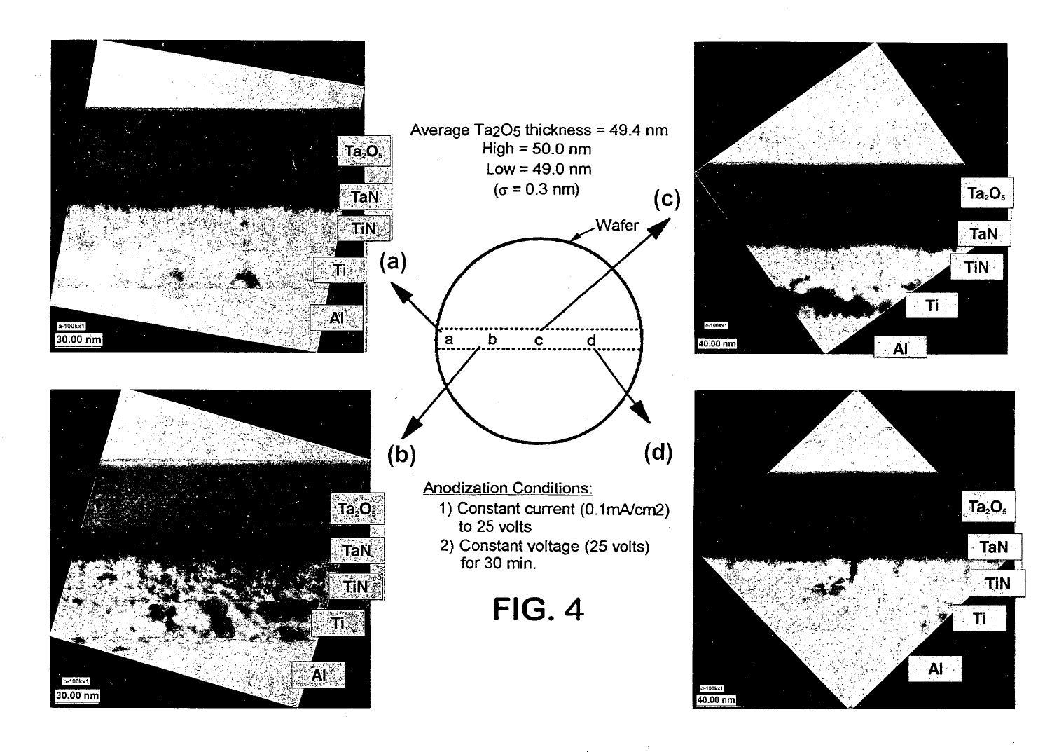

FIG. 4 shows TEM cross-section images corresponding to areas a, b, c, and d across a 200 mm circular wafer. The anodic oxide was measured to have an average thickness of 49.4 nm, with a high of 50.0 nm and a low of 49.0 nm, with a standard deviation of 0.6%, indicating very good process control in forming uniformly thick anodized films on relatively large substrates using the described method and apparatus.

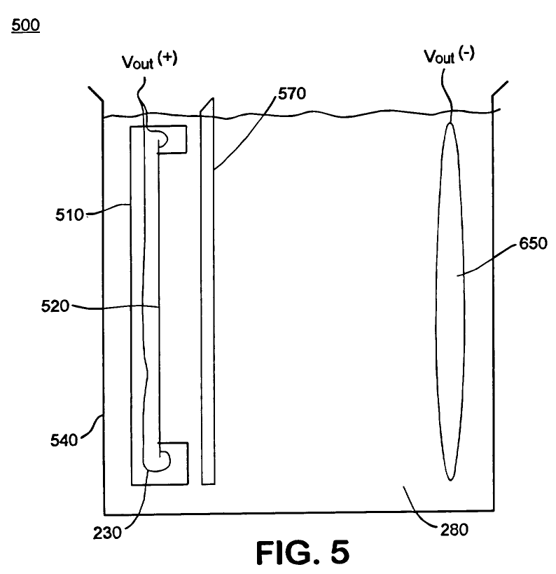

In an alternative embodiment, anodizing apparatus 500 may be of a so called “paddle cell flow” type as shown in FIG. 5.

The paddle cell contains a counter-electrode or cathode placed parallel to the anode. The anode and cathode can be placed in either a vertical or horizontal orientation. A vertical configuration may be preferable in some applications to allow escape of any gases that are produced during the anodization process. A paddle moving parallel to the wafer surface and executing a reciprocating motion with the aid of an external motor may be used to provide agitation of the electrolyte. An electrolyte solution such as citric acid, acetic acid, boric acid phosphoric acid tartaric acid or sulfuric acid preferably flows between the anode and cathode. In the event that the paddle is not moving, or is otherwise not present, electrolyte flow may be effected by recirculation to a holding compartment, or electrolyte tank. The wafer carrier assembly is lowered into the paddle cell flow assembly to bring the precursor film into contact with the electrolyte. Power from a controllable power supply is then applied between the precursor film on wafer through isolated electrical contacts and cathode, and anodization of the precursor film commences.

This apparatus may be similarly modified as was fountain flow apparatus 200, by using controlled power supply generator 660. The cathode material, electrolyte flow rate, and temperature ranges may also be the same in one aspect of this embodiment, as in fountain flow apparatus 200.

The method of operation of paddle cell flow apparatus 500 described above and illustrated in FIG. 5 will now be discussed with respect to anodizing a thick film on a large substrate. The method includes using apparatus 500, and includes the following steps:

i) depositing a blanket precursor film which may be the parent metal of the desired oxide to be formed, for example Ta, Al, W, Zr, Hf, Ti, Sb, Y, Bi, or Nb, or an alloy, multilayer, or doped version of such metals;

ii) providing electrical contact to a surface of the precursor film at a substrate edge with either a point or a continuous contact;

iii) placing the substrate into an electrolyte solution, for example citric acid, acetic acid, boric acid phosphoric acid tartaric acid or sulfuric acid, such that substantially all electrically conductive surfaces, e.g., pin contacts, the substrate edge and a backside of the substrate, are electrically isolated from the electrolyte, while ensuring that the surface of the precursor film is in contact with the electrolyte solution;

iv) applying a time-phased combination of constant current and constant voltage between the precursor film and an inert counter electrode, e.g., Pt or platinized Ti, which is also submerged in the electrolyte, to compensate for an ohmic voltage loss in the electrolyte.

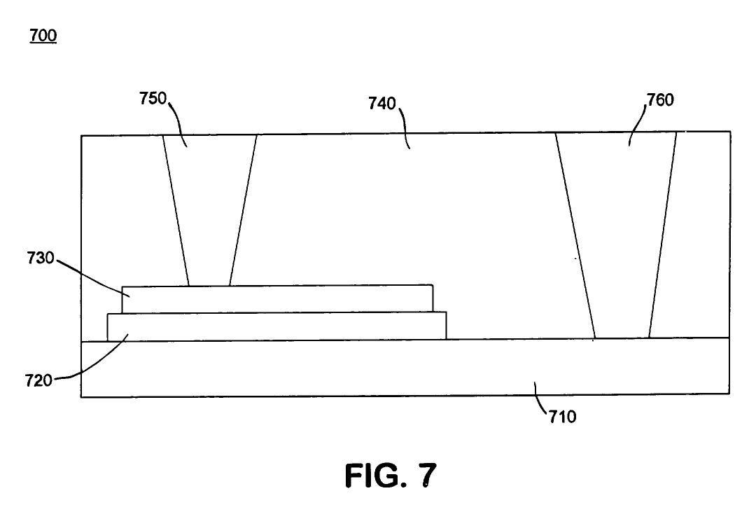

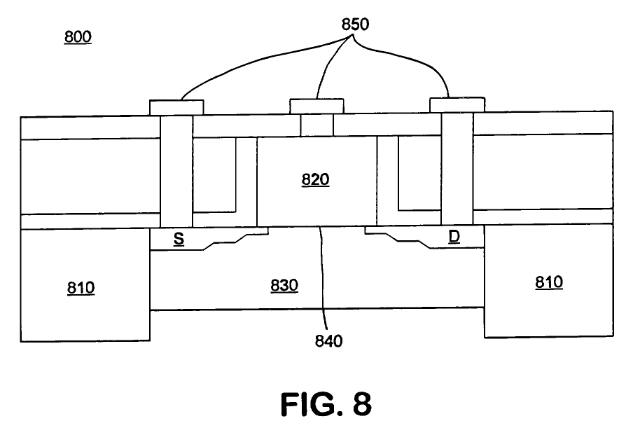

Representative devices which may be fabricated using the methods and apparatus described above, include a metal-insulator-metal (MIM) capacitor structure 700 as depicted in FIG. 7, and a transistor structure 800 as represented in FIG. 8.

MIM capacitor 700 includes bottom metal electrode 710, high dielectric content film (“high k” film) 720, top metal electrode 730, interlayer dielectric 740; top electrode contact 750, and bottom electrode contact 760. High k film 720 is preferably formed using the apparatus and method described, and may be Ta₂O₅, having a relative dielectric constant k≈25 or more, for example.

Metal gate transistor 800 may include source (S) and drain (D) regions, isolation regions 810, metal gate 820 over semiconductor channel region 830 region between the S and D, where metal gate 820 is separated from semiconductor channel region 830 by high k dielectric film 840. Conductive lines 850 preferably connect to the source (S), metal gate 820, and drain (D) regions. High k dielectric film 840 may advantageously be formed by the apparatus and methods described.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed as new and desired to be protected by Letters Patent of the United States is:

1. A method of fabricating a uniformly thick film of an anodized precursor film on a substrate, comprising:
depositing a precursor film on the substrate;
providing at least one electrical contact to a surface of said precursor film close to an edge of said substrate;
exposing the precursor film to an electrolyte;
isolating the at least one electrical contact from the electrolyte;
applying an anodic treatment to the precursor film exposed to the electrolyte to convert the precursor film to an anodized film; and
compensating for an ohmic voltage drop of the electrolyte.

2. The method of claim 1, further comprising rotating said substrate during said step of applying an anodic treatment.

3. The method of claim 1, wherein said depositing a precursor film includes depositing the precursor film over essentially an entire surface of the substrate.

4. The method of claim 1, wherein said providing at least one electrical contact includes providing said at least one electrical contact at a distance in the range of 0.05 to 1 cm from said substrate edge.

5. The method of claim 1, wherein said providing said at least one electrical contact includes providing said at least one electrical contact at a distance in the range of 0.05 to 0.5 cm from said substrate edge.

6. The method of claim 1, wherein said providing said at least one electrical contact includes providing said at least one electrical contact at a distance in the range of 0.05 to 0.1 cm from said substrate edge.

7. The method of claim 1, wherein said depositing a precursor film includes depositing the precursor film over essentially an entire surface of the substrate except for a region close to the substrate edge.

8. The method of claim 1, wherein said depositing a precursor film includes depositing a precursor film comprising at least two layers.

9. The method of claim 1, wherein said providing at least one electrical contact includes providing plurality of electrical contacts to the precursor film at a plurality of points arranged symmetrically with respect to a center of the substrate.

10. The method of claim 1, further comprising pumping the electrolyte from a storage tank into a region wherein the precursor film is exposed to the electrolyte.

11. The method of claim 1, further comprising controlling a flow rate of the electrolyte.

12. The method of claim 11, further comprising controlling a flow rate of the electrolyte to be between the range of 0 to 6 gal/min.

13. The method of claim 1, further comprising controlling a temperature of the electrolyte.

14. The method of claim 13, further comprising controlling a temperature of the electrolyte to be in the range of 10 to 50 degrees Celsius.

15. The method of claim 1, further comprising filtering the electrolyte.

16. The method of claim 1, wherein said applying an anodic treatment to the precursor film includes applying a constant voltage between the substrate and a counter electrode.

17. The method of claim 16, wherein said constant voltage is applied between the substrate and the counter electrode for a period of time sufficient for an anodization current to be reduced to a value less than 10% of an initial anodization current value.

18. The method of claim 16, wherein said constant voltage is applied between the substrate and the counter electrode for a period of time sufficient for an anodization current to be reduced to a value less than 1% of an initial anodization current value.

19. The method of claim 1, wherein said applying an anodic treatment to the precursor film includes applying a constant current between the substrate and a counter electrode.

20. The method of claim 19, wherein said constant current is applied between the substrate and the counter electrode until a threshold value of voltage is attained between the substrate and the counter electrode.

21. The method of claim 20, wherein said attained value of voltage between the substrate and the counter electrode includes an anodization voltage sufficient to achieve a desired thickness of the anodized film.

22. The method of claim 1, wherein said applying an anodic treatment to the precursor film includes applying essentially a constant current between the substrate and a counter electrode until a desired voltage is reached, followed by applying essentially a constant voltage between the substrate and the counter electrode.

23. The method of claim 22, wherein said constant voltage is applied between the substrate and the counter electrode for a period of time sufficient for an anodization current to be reduced to a value less than 10% of an initial anodization current.

24. The method of claim 22, wherein said constant voltage is applied between the substrate and the counter electrode for a period of time sufficient for an anodization current to be reduced to a value less than 1% of an initial anodization current.

25. The method of claim 1, further comprising depositing at least one conductive underlayer on said substrate before said depositing the precursor film.

26. The method of claim 25, wherein said depositing at least one conductive underlayer on said substrate includes depositing one of the group consisting of Al, Ti, TiN, W, Pt, Cr, and Mo.

27. The method of claim 25, wherein said depositing at least one conductive underlayer on said substrate includes depositing Cu.

28. The method of claim 1, wherein said depositing said precursor film includes depositing the precursor film on at least one semiconductor layer.

29. The method of claim 28, wherein said depositing the precursor film on at least one semiconductor layer includes depositing the precursor film on a layer of doped Si.

30. The method of claim 1, wherein said depositing the precursor film on the substrate includes depositing an oxide on the substrate.

31. The method of claim 1, wherein said depositing the precursor film on the substrate includes depositing one of the group consisting of Ti, Hf, Nb, Zr, Al, W, Y, Bi, and Sb.

32. The method of claim 1, wherein said exposing the precursor film to an electrolyte includes exposing the precursor film to one of the group consisting of citric acid, acetic acid, boric acid, phosphoric acid, tartaric acid, and sulfuric acid.

33. An apparatus for forming an anodized film on a precursor film located on a substrate, comprising:
a wafer carrier which holds said substrate;
at least one electrical contact within said wafer carrier, said at least one electrical contact being in contact with said precursor film;
a container having an electrolyte therein;
a counter electrode located in said container and covered by the electrolyte;
said wafer carrier being arranged so as to be immersed in the electrolyte to provide exposure of the precursor film to the electrolyte in the container, while isolating said at least one electrical contact from exposure to the electrolyte; and
means for compensating for an ohmic loss in the electrolyte,
wherein the at least one electrical contact and the counter-electrode are operatively connected to the means for compensating.

34. The apparatus of claim 33, wherein the container comprises a cup assembly.

35. The apparatus of claim 34, further comprising rotating means for rotating said wafer carrier while said precursor film is in contact with said electrolyte.

36. The apparatus of claim 35, wherein said rotating means is further adapted to move said wafer carrier into and out of said cup assembly.

37. The apparatus of claim 34, further comprising means for moving said wafer carrier into and out of said cup assembly.

38. The apparatus of claim 34, further comprising a diffuser plate in said cup assembly between said cathode and said wafer carrier.

39. The apparatus of claim 33, further comprising a pump operatively connected to said container.

40. The apparatus of claim 39, wherein said pump provides electrolyte to said cup assembly, and said electrolyte forms a fountainhead which overflows an edge of said cup assembly.

41. The apparatus of claim 39, further comprising a filter operatively connected to said pump.

42. The apparatus of claim 39, further comprising a controller to control a flow rate of the electrolyte through the pump.

43. The apparatus of claim 33, wherein the means for compensating for an ohmic loss in the electrolyte at least provides a constant current.

44. The apparatus of claim 43, wherein the means for compensating for an ohmic loss in the electrolyte provides the constant current until a threshold voltage between said substrate and said counter electrode is reached.

45. The apparatus of claim 43, wherein the means for compensating for an ohmic loss in the electrolyte at least provides a constant voltage after providing the constant current.

46. The apparatus of claim 45, wherein said constant voltage is equal to a voltage attained between the substrate and the counter electrode.

47. The apparatus of claim 45, wherein said constant voltage compensates for a voltage drop in said electrolyte.

48. The apparatus of claim 33, wherein the means for compensating for an ohmic loss in the electrolyte at least provides a constant voltage.

49. The apparatus of claim 48, wherein said constant voltage is equal to a voltage attained between the substrate and the counter electrode.

50. The apparatus of claim 48, wherein said constant voltage is applied for a period of time required for an anodization current to be reduced to a level which is less than 10% of an initial anodization current.

51. The apparatus of claim 48, wherein said constant voltage is applied for a period of time required for an anodization current to be reduced to a level which is less than 1% of an initial anodization current.

52. The apparatus of claim 48, wherein said constant voltage compensates for a voltage drop in the electrolyte.

53. The apparatus of claim 33, wherein the means for compensating for an ohmic loss in the electrolyte includes a programmable power supply which is at least capable of providing both a time-phased constant current and a time-phased constant voltage.

54. The apparatus of claim 33, wherein a temperature of the electrolyte is controlled to be in the range of 10 to 50 degrees Celsius.

55. The apparatus of claim 33, further comprising a heater to heat the electrolyte.

56. The apparatus of claim 55, further comprising a temperature controller operatively connected to the heater to control a temperature of the electrolyte.

57. The apparatus of claim 33, wherein said counter electrode is inert.

58. The apparatus of claim 57, wherein said counter electrode is one of the group consisting of Pt and Platinized Ti.

59. The apparatus of claim 33, wherein a shape of said counter electrode is essentially the same as a shape of the substrate.

60. A method of anodizing a uniformly thick film on a substrate using an anodization apparatus comprising a wafer carrier which holds the substrate; at least one electrical contact within the wafer carrier; a container having an electrolyte therein; a counter electrode located in the cup assembly; a controllable power supply, the at least one electrical contact being connected to a terminal of the controllable power supply and the counter electrode being connected to a different terminal of the controllable power supply, the wafer carrier being adapted to move the substrate into contact with the electrolyte in the container, the method comprising:
depositing a precursor film on the substrate;
providing the at least one electrical contact to a surface of said precursor film close to an edge of the substrate;
immersing said precursor film in the electrolyte;
isolating the at least one electrical contact from the electrolyte;
applying an anodic treatment to the precursor film exposed to the electrolyte to convert the precursor film to an anodized film,
said anodic treatment including providing, from the controllable power supply, a constant current followed by a constant voltage;. and
compensating for a voltage drop in the electrolyte to produce essentially a uniform anodized film.

61. A method of fabricating a capacitor having a uniformly thick anodized film of a precursor film therein, comprising:
providing a first conductive layer on a substrate;
depositing a precursor film on the first conductive layer;
providing at least one electrical contact to a surface of said precursor film close to an edge of said substrate;
exposing the precursor film to an electrolyte;
isolating the at least one electrical contact from the electrolyte;
applying an anodic treatment to the precursor film exposed to the electrolyte to convert the precursor film to an anodized film;
providing a second conductive layer on the anodized film; and
compensating for a voltage drop in the electrolyte to produce essentially a uniform anodized film.

62. A method of fabricating a transistor having a uniformly thick anodized film of a precursor film therein, comprising:
providing a semiconductor layer on a substrate;
depositing a precursor film on the semiconductor layer;
providing at least one electrical contact to a surface of said precursor film close to an edge of said substrate;
exposing the precursor film to an electrolyte;
isolating the at least one electrical contact from the electrolyte;
applying an anodic treatment to the precursor film exposed to the electrolyte to convert the precursor film to an anodized film;
providing a conductive layer on the anodized film; and
compensating for a voltage drop in the electrolyte to produce essentially a uniform anodized film.

63. A process of fabricating a uniformly thick anodized film of a precursor film on a large substrate, comprising:
depositing the precursor film on the large substrate, said precursor film having a thickness which exceeds a desired thickness of the anodized film;
making electrical contact with a surface of said precursor film close to a substrate edge;
immersing the substrate into an electrolyte;
ensuring that all electrical contacts as well as all conducting substrate surfaces other than the precursor film are isolated from the electrolyte;
applying an anodic treatment to the precursor film exposed to the electrolyte; and
compensating for a voltage drop in the electrolyte to produce essentially a uniform anodized film.

64. An anodization process for forming a uniformly thick anodized film on a substrate, comprising compensating an applied anodization voltage for an ohmic voltage drop of an electrolyte.

65. A single-step anodization process for forming a uniformly thick anodized film on a substrate, comprising applying an anodizing voltage that has been compensated to account for an ohmic voltage loss resulting from a flow of current through an electrolyte.

66. A two step anodization process for forming a uniformly thick anodized film on a substrate, comprising:
applying a constant current to the substrate until a threshold voltage equal to an anode voltage plus a voltage drop in an electrolyte is attained between the substrate and a counter electrode; and
thereafter applying a constant voltage equal to the anode voltage, wherein the anode voltage is a voltage necessary to obtain a desired thickness of the anodized film in an absence of the voltage drop in the electrolyte.

67. The process of claim 66, wherein the threshold voltage is attained by linearly varying a voltage.
